(19) United States
(12) Patent Application Publication
(10) Pub. No.: US 2026/0059907 A1
(43) Pub. Date: Feb. 26, 2026

(54) LENS STRUCTURES FOR LIGHT-EMITTING DIODE (LED) CHIPS IN LED PACKAGES

(71) Applicant: CreeLED, Inc., Durham, NC (US)

(72) Inventors: David Suich, Durham, NC (US); F James Claire, Chapel Hill, NC (US); Joseph G. Sokol, Durham, NC (US); Robert Wilcox, Rolesville, NC (US); Colin Blakely, Raleigh, NC (US)

(21) Appl. No.: 18/812,005

(22) Filed: Aug. 22, 2024

(51) Int. Cl. H01L 33/58; H01L 25/075

(52) U.S. Cl. CPC H10H 20/855; H01L 25/0753

(57) ABSTRACT

Light-emitting diode (LED) devices and more particularly lens structures for LED chips in LED packages are disclosed. Lens structures include complex shapes for achieving various emission patterns in LED packages. Complex lens shapes include arrangements of multiple lenses within a same LED package. A first lens is arranged on an LED chip with a self-forming shape, followed by a second lens that encapsulates the first lens. The self-forming shape of the first lens provides the ability to have lens widths that taper inward and depressions positioned relative to the underlying LED chip. Combinations of shapes for the first and second lenses may be configured to collectively provide tailored light emission profiles in corresponding LED packages.

### FIELD OF THE DISCLOSURE

The present disclosure relates to light-emitting diode (LED) devices, and more particularly to lens structures for LED chips in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to lens structures for LED chips in LED packages. Lens structures include complex shapes for achieving various emission patterns in LED packages. Complex lens shapes include arrangements of multiple lenses within a same LED package. A first lens is arranged on an LED chip with a self-forming shape, followed by a second lens that encapsulates the first lens. The self-forming shape of the first lens provides the ability to have lens widths that taper inward and depressions positioned relative to the underlying LED chip. Combinations of shapes for the first and second lenses may be configured to collectively provide tailored light emission profiles in corresponding LED packages.

In one aspect, an LED package comprises: a support structure; an LED chip mounted on the support structure, the LED chip having a first width in a first direction parallel to the support structure; a first lens on the LED chip, the first lens comprising: a second width in the first direction, the second width defining a portion of the first lens that is closest to the LED chip, and the second width being less than or equal to the first width of the LED chip; and a third width in the first direction, the third width defining a largest dimension of the first lens in the first direction, the third width being greater than the first width of the LED chip; and a second lens on the first lens and the support structure, the second lens covering the first lens and extending on a portion of the support structure adjacent to the LED chip. In certain embodiments, the second width defines an interface between the first lens and the LED chip. The LED package may further comprise a lumiphoric material layer on the LED chip, wherein the second width defines an interface between the first lens and the lumiphoric material layer. In certain embodiments, the lumiphoric material layer laterally extends on the portion of the support structure adjacent to the LED chip. The LED package may further comprise a wire bond electrically coupled to a top surface of the LED chip, the wire bond extending through a portion of the first lens and a portion of the second lens. In certain embodiments, a surface of the first lens forms an inward depression in a direction toward the LED chip. In certain embodiments, the inward depression is centered with respect to the LED chip. In certain embodiments, the first lens forms a ring of increased thickness around a perimeter of the inward depression. In certain embodiments, a bottom of the inward depression forms a curved surface. In certain embodiments, the inward depression of the first lens is a first inward depression; and a surface of the second lens forms a second inward depression in a direction toward the first inward depression. In certain embodiments, the second lens extends past perimeter edges of the support structure in the first direction. In certain embodiments, one or more side surfaces of the second lens inwardly taper toward a top surface of the support structure. In certain embodiments, the support structure comprises a submount with electrical traces. In certain embodiments, the support structure comprises a lead frame structure with a housing.

In another aspect, an LED package comprises: a support structure; a plurality of LED chips mounted on the support structure, each LED chip of the plurality of LED chips having a first width in a first direction parallel to the support structure; a separate first lens on each LED chip of the plurality of LED chips, each first lens comprising: a second width in the first direction, the second width defining a portion of each first lens that is closest to a corresponding LED chip of the plurality of LED chips, and the second width being less than or equal to the first width; and a third width in the first direction, the third width defining a largest dimension of each first lens in the first direction, the third width being greater than the first width; and a second lens on the plurality of LED chips and the support structure, the second lens covering each first lens and extending on a portion of the support structure adjacent to the plurality of LED chips. In certain embodiments, the second lens is positioned between neighboring LED chips of the plurality of LED chips. In certain embodiments, the support structure comprises a lead frame structure with a housing, and the plurality of LED chips are positioned within a same recess of the housing. The LED package may further comprise a lumiphoric material layer positioned in the recess and covering the plurality of LED chips, wherein each first lens is spaced from the plurality of LED chips by a portion of the lumiphoric material layer.

In another aspect, an LED package comprises: a support structure; an LED chip mounted on the support structure; a first lens on the LED chip and on a portion of the support structure adjacent to the LED chip, the first lens comprising one or more side surfaces that inwardly taper in a direction toward the support structure; and a second lens on the first lens and the support structure, the second lens covering the first lens and extending on a portion of the support structure adjacent to the first lens. In certain embodiments, a surface of the first lens forms an inward depression in a direction toward the LED chip. In certain embodiments, the inward depression is centered with respect to the LED chip. In certain embodiments: the inward depression of the first lens is a first inward depression; and a surface of the second lens forms a second inward depression in a direction toward the first inward depression. The LED package may further comprise a light-altering material having a white color and positioned between the second lens and the support structure. In certain embodiments, a portion of the light-altering material is positioned between the first lens and the support structure in a direction perpendicular to the support structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an exemplary light-emitting diode (LED) package that includes first and second lenses on a support structure according to principles of the present disclosure.

FIG. 2 is a cross-sectional view of an LED package that is similar to the LED package of FIG. 1 for embodiments that further include a lumiphoric material layer.

FIG. 3A is a cross-sectional view at an initial step in a fabrication sequence for forming multiple ones of the LED package of FIG. 1.

FIG. 3B is a cross-sectional view at a subsequent fabrication step from FIG. 3A for forming the lens.

FIG. 3C is a cross-sectional view at a subsequent fabrication step from FIG. 3B for forming the second lens.

FIG. 4 is a cross-sectional view of an LED package similar to the LED package of FIG. 1 for embodiments that include one or more wire bonds for providing electrical connections to the LED chip.

FIG. 5 is a cross-sectional view of an LED package similar to the LED package of FIG. 1 for embodiments where the first lens further forms a depression in a surface thereof.

FIG. 6 is a cross-sectional view of an LED package similar to the LED package of FIG. 5 for embodiments with another shape for the depression.

FIG. 7 is a cross-sectional view of an LED package similar to the LED package of FIG. 6 for embodiments where the second lens forms a complex shape.

FIG. 8 is a cross-sectional view of an LED package similar to the LED package of FIG. 7 for embodiments where the second lens forms another complex shape.

FIG. 9 is a cross-sectional view of an LED package similar to the LED package of FIG. 7 for embodiments where the second lens does not include the inward depression of FIG. 7.

FIG. 10 is a cross-sectional view of an LED package similar to the LED package of FIG. 1 for embodiments that include multiple LED chips underneath the second lens.

FIG. 11 is a cross-sectional view of an LED package similar to the LED package of FIG. 1 for embodiments where the first lens extends on portions of the support structure that are adjacent to the LED chip.

FIG. 12 is a cross-sectional view of an LED package similar to the LED package of FIG. 11 for embodiments that include a light-altering material on the support structure.

FIG. 13 is a cross-sectional view of an LED package similar to the LED package of FIG. 1 for embodiments where the support structure is a lead frame structure.

FIG. 14 is a cross-sectional view of an LED package similar to the LED package of FIG. 13 for embodiments that include multiple LED chips.

FIG. 15 is a cross-sectional view of an LED package similar to the LED package of FIG. 14 for embodiments that include a lumiphoric material layer.

FIG. 16 is a schematic diagram of a portion of an LED device, such as a display screen, for example, an indoor and/or outdoor screen comprising, in general terms, a display panel including a large number of LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to lens structures for LED chips in LED packages. Lens structures include complex shapes for achieving various emission patterns in LED packages. Complex lens shapes include arrangements of multiple lenses within a same LED package. A first lens is arranged on an LED chip with a self-forming shape, followed by a second lens that encapsulates the first lens. The self-forming shape of the first lens provides the ability to have lens widths that taper inward and depressions positioned relative to the underlying LED chip. Combinations of shapes for the first and second lenses may be configured to collectively provide tailored light emission profiles in corresponding LED packages.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to both single-chip and multiple-chip LED packages. In multiple-chip LED packages, multiple LED chips are arranged within a common recess or on a common submount and sometimes beneath a common lens of an LED package. In certain embodiments, LED packages may include red, green, and blue LED chips such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Cai-x-ySrxEuyAlSiN3) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure or a submount.

Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

In conventional LED packages, lenses are typically formed by a molding process that provides a lens shape on the support structure. The molding process may include confining an encapsulant material to the shape of a lens with a mold block, curing of the encapsulant material, followed by removal of the mold block. In such applications, the shape of the lens may form various shapes, such as domes or hemispherical lenses. Although there is some ability to change lens shapes by changing mold blocks, the types and shapes of lenses that are manufacturable are limited by the ability to remove mold blocks from the lenses without damaging or otherwise changing the lens shape.

According to aspects of the present disclosure, complex lens structures relative to support structures are provided by utilizing encapsulant materials with increased thixotropic properties and/or viscosity. By way of example, silicone with increased thixotropic properties and/or viscosity may be used to form complex lens structures of the present disclosure. Such encapsulant materials may be manipulated to achieve desired shapes for targeted emission profiles before curing. Since such encapsulant materials may hold their shape for curing without conventional molds, shape limitations associated with mold release may be avoided. Accordingly, encapsulant materials for lenses may exhibit self-forming shapes or as dispensed shapes. Exemplary lenses may form self-doming shapes or even dual doming shapes as they are dispensed. Adjustments to material properties of the encapsulant material and/or dispensing properties such as dispensing pressure may be adjusted to provide different shapes for targeted emission profiles.

In certain aspects, complex lens structures include a first lens on an LED chip and a larger second lens that encapsulates the first lens on the support structure. The first lens may be formed with materials capable of achieving complex shapes without limitations associated with molding techniques. The second lens may be sequentially formed such that the first lens is essentially embedded within the second lens. The second lens may be formed by molding or with a second process similar to the first lens if more complex shapes are desired for the second lens. In certain embodiments, both the first lens and the second lens comprise silicone, with the silicone of the first lens having increased thixotropic properties and/or viscosity relative to the silicone of the second lens. In other embodiments where the second lens is formed in a similar manner as the first lens, both lenses may have the same encapsulant material.

In certain embodiments, a perimeter of the first lens may be formed to extend beyond sidewalls of the LED chip. In such configurations, sides of the first lens may inwardly taper toward the LED chip with a shape not possible with conventional molding. In further aspects, a complex lens shape may include an inward dimple or depression formed in a top surface of the first lens and/or the second lens. The amount a first lens extends beyond sidewalls of the LED chip and/or dimensions of the inward dimple may be tailored to achieve desired emission patterns of the overall LED package, such as increased columnar emission patterns and/or wider emission patterns.

FIG. 1 is a cross-sectional view of an exemplary LED package 10 that includes first and second lenses 12-1, 12-2 on a support structure 14 according to principles of the present disclosure. By way of example, the support structure 14 in FIG. 1 includes a submount 16 with package mounting pads 18-1 to 18-3 arranged on a bottom surface thereof for mounting the LED package 10 to another surface. In certain embodiments, certain package mounting pads (e.g., 18-1 and 18-2) may provide electrical connections for the LED package 10 and other package mounting pads (e.g., 18-3) may form a thermal pad that is electrically isolated. Depending on the electrical configuration, all of the package mounting pads 18-1 to 18-3 may provide electrical connections along with heat dissipation. The LED chip 20 is mounted on a top surface of the support structure 14, opposite the package mounting pads 18-1 to 18-3 by way of bonding anode and cathode pads of the LED chip 20 to corresponding attach pads 22, 24 of the support structure 14. The attach pads 22, 24 may be electrically coupled to corresponding ones of the package mounting pads 18-1 to 18-3 by way of vias that extend within the submount 16. While FIG. 1 is described in the context of the support structure 14 including a submount 16, the principles described may also be applicable to embodiments where the support structure embodies a lead frame structure with a housing.

As mentioned above, sizes of structures or regions may be exaggerated relative to other structures or regions for illustrative purposes and, thus, are provided to illustrate the general structures of the present subject matter and may or may not be drawn to scale. In this regard, the principles described herein are applicable to embodiments where relative sizes of the LED chip 20 and the first lens 12-1 are reduced relative to the support structure 14 and the second lens 12-2.

As illustrated in FIG. 1, the LED package 10 includes a complex lens structure formed by the first lens 12-1 and the second lens 12-2. The first lens 12-1 may be formed on and bound by the LED chip 20, while having a shape that laterally extends beyond a perimeter of the LED chip 20. For example, the LED chip 20 has a first width W1 defined in a direction parallel to the support structure 14 and/or submount 16. The first lens 12-1 has a second width W2 defining a portion of the lens closest to the LED chip 20, such as an interface between the first lens 12-1 and the LED chip 20. The second width W2 may be less than or equal to the first width W1. The first lens 12-1 may flare outward from the LED chip 20, thereby forming a third width W3 that defines a largest lateral dimension of the first lens 12-1. The third width W3 is greater than the 2nd width W2, thereby forming a shape that is not bound by conventional mold release limitations. For illustrative purposes, the orientation of the superimposed dashed lines for W1, W2, and W3 are all provided in a same first direction that is parallel to the support structure 14.

After the first lens 12-1 is formed, the second lens 12-2 may then be formed on the first lens 12-1 and the support structure 14. The second lens 12-2 may cover the first lens 12-1 and extend on portions of the support structure 14 that are adjacent the LED chip 20. In this regard, the second lens 12-2 may essentially encapsulate the first lens 12-1 on the support structure 14. For example, the second lens 12-2 may be formed by dispensing and/or molding to the support structure 14. In certain embodiments, the second lens 12-2 is bound by a surface of the support structure 14 such that a perimeter of the second lens 12-2 contacts the support structure 14 in a position inset from a perimeter edge of the support structure 14. In such embodiments, the second lens 12-2 may be devoid of a flash extension that extends to cover the remaining surfaces of the support structure 14, thereby allowing easier singulation during fabrication. In further embodiments, the entire perimeter edge of the second lens 12-2 is on a top surface of the support structure 14.

During operation, certain light generated by the LED chip 20 may first pass through the first lens 12-1 before the second lens 12-2. The shape of the first lens 12-1 may increase light in certain directions between the first lens 12-1 and the second lens 12-2. Accordingly, overall emissions from the LED package 10 may be tailored for targeted applications by controlling the shape of the first lens 12-1 within the LED package 10. In the example provided by FIG. 1, the first lens 12-1 forms a ball shape with progressively outwardly curved surfaces from the second width W2 to the third width W3. In this example, laterally angled light emissions from the LED chip 20 that interact with these progressively outwardly curved surfaces may be redirected toward emission directions normal to the support structure 14 for increased columnar emissions from the LED package 10.

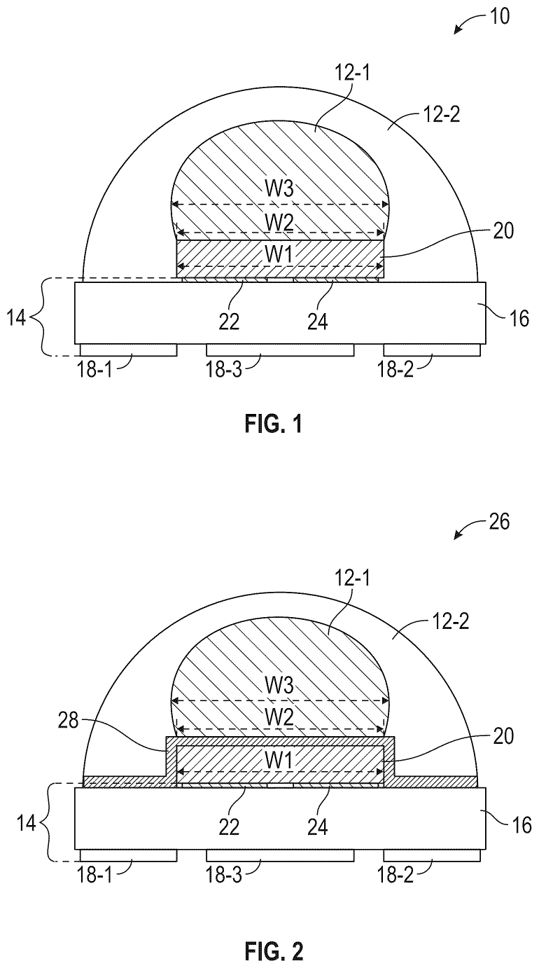

FIG. 2 is a cross-sectional view of an LED package 26 that is similar to the LED package 10 of FIG. 1 for embodiments that further include a lumiphoric material layer 28. In certain embodiments, the lumiphoric material layer 28 may be formed on the LED chip 20 before the first lens 12-1 and the second lens 12-2 are formed. Accordingly, the first lens 12-1 may be formed on the lumiphoric material layer 28 and the second width W2 defines an interface between the first lens 12-1 and the lumiphoric material layer 28. The relative dimensions of the first, second, and third widths W1, W2, and W3 may have the same relationship as described above for FIG. 1. The lumiphoric material layer 28 may also laterally extend on the support structure 14 adjacent to the LED chip 20 and underneath the second lens 12-2.

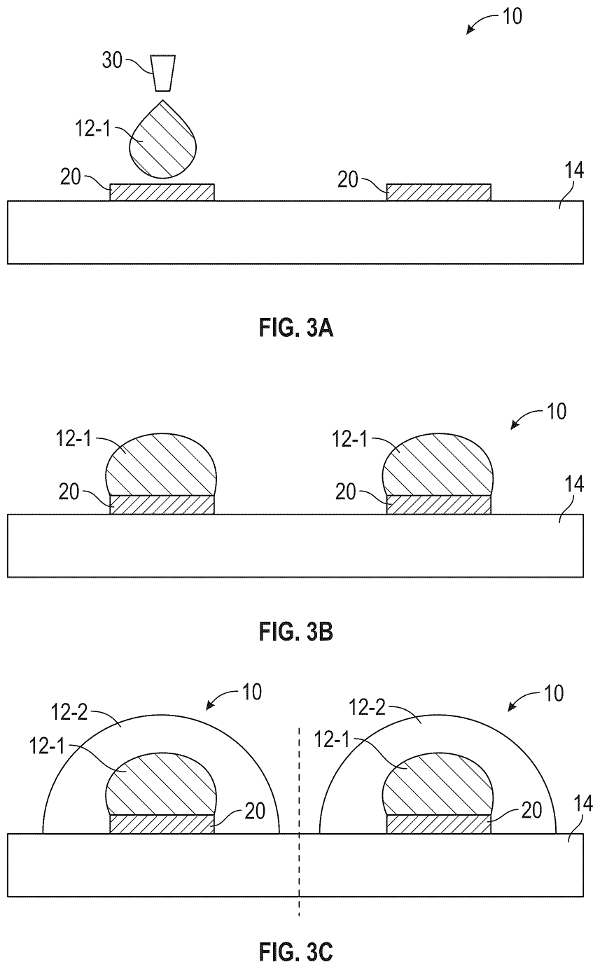

FIGS. 3A to 3C illustrate a general fabrication sequence for forming the LED package 10 of FIG. 1. In each of FIGS. 3A to 3C, the support structure 14 is generally illustrated and may embody either submount or lead frame structures. For illustrative purposes, FIGS. 3A to 3C are provided from the perspective of two LED chips 20. In practice, FIGS. 3A to 3C may represent bulk manufacturing of many LED packages at a panel level. While FIGS. 3A to 3C are described in the context of the LED package 10 of FIG. 1, the principles described are also applicable for forming the first lens 12-1 and second lens 12-2 of the LED package 26 of FIG. 2.

FIG. 3A is a cross-sectional view at an initial step in a fabrication sequence for forming multiple ones of the LED package 10 of FIG. 1. In FIG. 3A, several LED chips 20 have already been mounted or otherwise provided on the support structure 14. Material for the first lens 12-1 may be dispensed by way of a nozzle 30 on the LED chips 20. As described above, such material may be selected with increased thixotropic properties and/or viscosity so that the material may hold its shape after dispensing without the need for conventional molding techniques. The nozzle 30 may generally represent an element of a jet pump or an engineered fluid dispensing system.

FIG. 3B is a cross-sectional view at a subsequent fabrication step from FIG. 3A for forming the first lens 12-1. After the dispensing step of FIG. 3A, the lens 12-1 for each LED chip 20 may form a dispensed shape with various widths as described above with respect to the first, second, and third widths W1, W2, and W3 of FIG. 1. Due to the nature of the material of the lens 12-1, the as-dispensed shape may retain its form on each LED chip 20. In certain embodiments, perimeter edges of the LED chip 20 may bound or confine an interface with the lens 12-1 while other portions of the lens 12-1 may extend outward and past perimeter edges of the LED chip 20. After all lenses 12-1 are formed with their respective dispensed shapes, the material of the lenses 12-1 may be cured at the fabrication step of FIG. 3B.

FIG. 3C is a cross-sectional view at a subsequent fabrication step from FIG. 3B for forming the second lens 12-2. The second lens 12-2 may be formed by compression molding and curing the second lens 12-2 in place to cover the first lens 12-1 and portions of the support structure 14 adjacent the LED chips 20. In alternative embodiments where complex shapes are desired for the second lens 12-2, the second lens 12-2 may be formed by a similar process as described above for the first lens 12-1. Finally, individual ones of the LED package 10 may be separated from one another along the vertical dashed line superimposed in FIG. 3C. The separation step may involve singulation via sawing, cutting, and/or breaking.

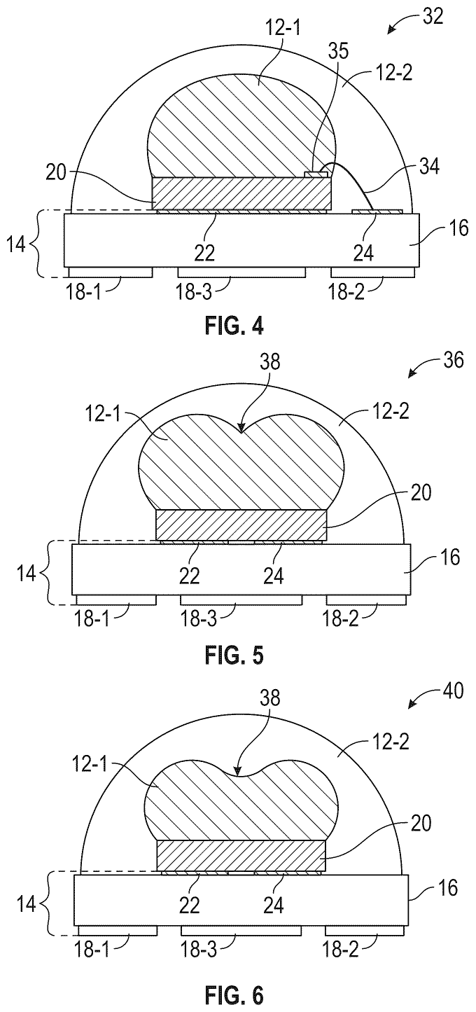

FIG. 4 is a cross-sectional view of an LED package 32 similar to the LED package 10 of FIG. 1 for embodiments that include one or more wire bonds 34 for providing electrical connections to the LED chip 20. Instead of the flip-chip arrangement of the LED chip 20 in FIG. 1, the LED chip 32 of FIG. 4 includes at least one topside contact 35 and the wire bond 34 is provided to electrically connect with the attach pad 24. Due to the self-forming nature of the shape of the first lens 12-1, the wire bond 34 may be electrically coupled between the topside contact 35 and the attach pad 24 before material for the first lens 12-1 is dispensed and cured. The wire bond 34 extends from the topside contact 35 to a position outside the first lens 12-1, therefore the first lens 12-1 encapsulates only a portion of the wire bond 34. Such an arrangement would not be possible with conventional molding since the mold itself would distort and/or sever the pre-formed wire bond 34. In certain embodiments, the wire bond 34 extends through portions of both the first lens 12-1 and the second lens 12-2 such that a combination of the first and second lenses 12-1, 12-2 provide encapsulation for the wire bond 34.

FIG. 5 is a cross-sectional view of an LED package 36 similar to the LED package 10 of FIG. 1 for embodiments where the first lens 12-1 further forms a dimple or depression 38 in a surface thereof. The depression 38 may form inward in a direction towards the LED chip 20. For example, the depression 38 may form an inwardly angled surface that is effectively centered with respect to the LED chip 20. In this manner, increased light emissions that are normal to surface of the LED chip 20 may be redirected to wider angle emissions. From the cross-sectional view of FIG. 5, the first lens 12-1 may appear as a dual-dome lens with areas of increased thickness formed in a curved manner on either side of the depression 38. In certain embodiments, the depression 38 may form a generally circular shape that is centrally located about the first lens 12-1, such that the peaks of increased thickness represent a continuous ring that extends about and defines a perimeter boundary of the depression 38. As described above, the material of the first lens 12-1 is provided with sufficiently high viscosity to permit the first lens 12-1 to have a dispensed shape that is retained before curing. In certain embodiments, the material of the first lens 12-1 may be dispensed with increased pressure to effectively control formation of the depression 38. Adjustments to the dispensing pressure and/or width of an orifice of the nozzle 30 of FIG. 3A may be utilized to tailor dimensions, such as a depth and/or width of the depression 38 for achieving specific light emission patterns.

FIG. 6 is a cross-sectional view of an LED package 40 similar to the LED package 36 of FIG. 5 for embodiments with another shape for the depression 38. In FIG. 5, dispensing of the first lens 12-1 is controlled in a manner that forms the depression 38 with a curved bottom. In this manner, the depression 38 may form a wider base than the arrangement of FIG. 5, thereby providing a different emission pattern for light.

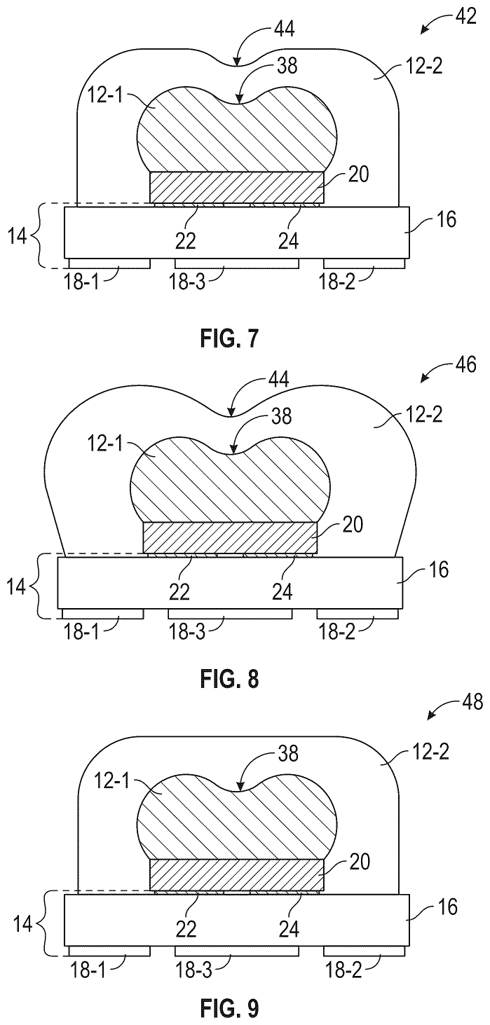

FIG. 7 is a cross-sectional view of an LED package 42 similar to the LED package 40 of FIG. 6 for embodiments where the second lens 12-2 forms a complex shape. As illustrated, the second lens 12-2 may include a depression 44 that is an inwardly curved surface. The depression 44 of the second lens 12-2 may be centered with respect to the depression 38 of the first lens 12-1 and/or the LED chip 20. In certain embodiments, side surfaces of the second lens 12-2 may extend toward the support structure 14 in a manner that allows the second lens 12-2 to be molded to the support structure 14. For example, the side surfaces of the second lens 12-2 may extend either perpendicular to a top surface of the support structure 14 or with an outward taper compatible with a mold release. In certain embodiments, the base of the second lens 12-2 may form a generally rectangular shape that corresponds with a rectangular shape of the support structure 14.

FIG. 8 is a cross-sectional view of an LED package 46 similar to the LED package 42 of FIG. 7 for embodiments where the second lens 12-2 forms another complex shape. In certain embodiments, the shape of the second lens 12-2 may be formed in a similar manner as the first lens 12-1 to avoid limitations associated with molding. For example, one or more side surfaces of the second lens 12-2 may inwardly taper toward the top surface of the support structure 14. Additionally, a lateral width of the second lens 12-2 in a direction parallel to the support structure 14 may extend past perimeter edges of the support structure 14. As illustrated, the first lens 12-1 and the second lens 12-2 may have the same or similar shapes in a nesting arrangement to further tailor light emissions in targeted patterns.

FIG. 9 is a cross-sectional view of an LED package 48 similar to the LED package 42 of FIG. 7 for embodiments where the second lens 12-2 does not include the inward depression 44 of FIG. 7. As with the embodiment of FIG. 7, the base of the second lens 12-2 may form a generally rectangular shape that corresponds with a rectangular shape of the support structure 14. As with other embodiments, the ability to mix and match the shapes of the first lens 12-1 relative to the second lens 12-2 provides increased ability to tailor light emissions exiting the LED package 48.

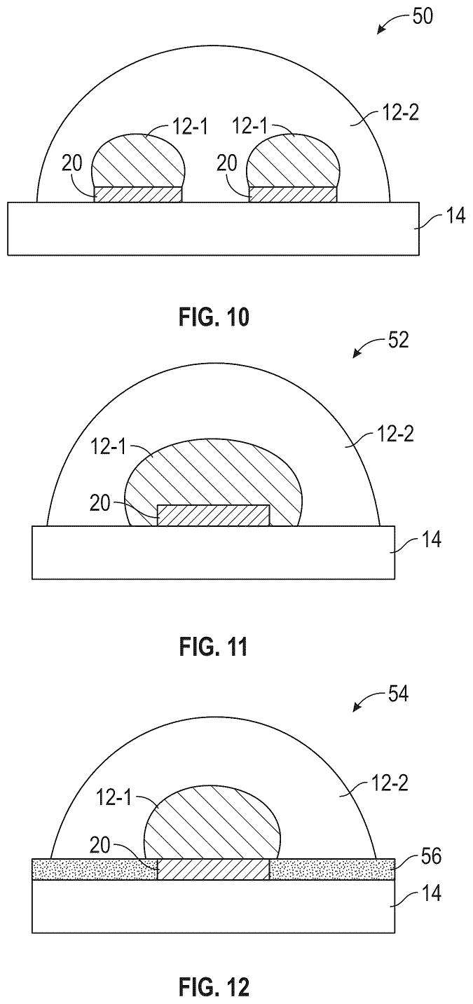

FIG. 10 is a cross-sectional view of an LED package 50 similar to the LED package 10 of FIG. 1 for embodiments that include multiple LED chips 20 underneath the second lens 12-2. Each of the LED chips 20 may include a separate first lens 12-1 with the same widths as described with respect to FIG. 1. Each of the first lenses 12-1 may be self-formed on the corresponding LED chip 20 as described with respect to FIGS. 3A and 3B, following by forming the second lens 12-2 to cover and encapsulate both LED chips 20 and corresponding first lenses 12-1. While the first lenses 12-1 of FIG. 10 are illustrated with the same shape as provided in FIG. 1, the first lenses 12-1 may have any of the self-forming shapes described above with respect to any of FIGS. 1 to 9. The second lens 12-2 may form a common encapsulant for covering both first lenses 12-1 and both LED chips 20. The second lens 12-2 may further extend on portions of the support structure 14 that are adjacent the LED chips 20, including portions that are between neighboring ones of the LED chips 20.

FIG. 11 is a cross-sectional view of an LED package 52 similar to the LED package 10 of FIG. 1 for embodiments where the first lens 12-1 extends on portions of the support structure 14 that are adjacent to the LED chip 20. In this regard, the first lens 12-1 may be formed by dispensing sufficient encapsulant material on the LED chip 20 such that it overflows onto the support structure 14. The first lens 12-1 may therefore encapsulant the LED chip 20, and the second lens 12-2 may encapsulate the first lens 12-1. The second lens 12-2 may have perimeter edges that are inset from perimeter edges of the support structure 14. The shape of the first lens 12-1 may have a shape that is not limited by conventional mold release technology, such as inwardly tapered surfaces toward the support structure 14. In certain embodiments, the first lens 12-1 may have any of the self-forming shapes described above with respect to any of FIGS. 1 to 9, including shapes with inward depressions as illustrated in FIGS. 5 to 9.

FIG. 12 is a cross-sectional view of an LED package 54 similar to the LED package 52 of FIG. 11 for embodiments that include a light-altering material 56 on the support structure 14. The light-altering material 56 may embody a layer of light-reflecting material positioned to reflect and/or redirect light in directions through the first and second lenses 12-1, 12-2. As described above, the light-altering material 56 may include at least one of fused silica, fumed silica, TiO₂, or metal particles suspended in a binder, such as silicone or epoxy for reflecting and/or refracting light. In certain embodiments, the light-altering material 56 may embody a white layer. The light-altering material 56 may further include carbon, silicon, or metal particles suspended in the binder in an arrangement for absorbing a portion of light for increased contrast. As illustrated, the light-altering material 56 may cover sidewalls of the LED chip 20 and portions of the support structure 14 adjacent to the LED chip 20. The first lens 12-1 may be formed on the LED chip and portions of the light-altering material 56. In this regard, a portion of the light-altering material 56 is between the first lens 12-1 and the support structure 14 in a perpendicular direction relative to the support structure 14. Moreover, the light-altering material 56 may also be positioned between the second lens 12-2 and the support structure 14 in a perpendicular direction relative to the support structure 14. In various embodiments, the light-altering material 56 may be implemented in any of the LED packages described above with respect to FIGS. 1 to 10.

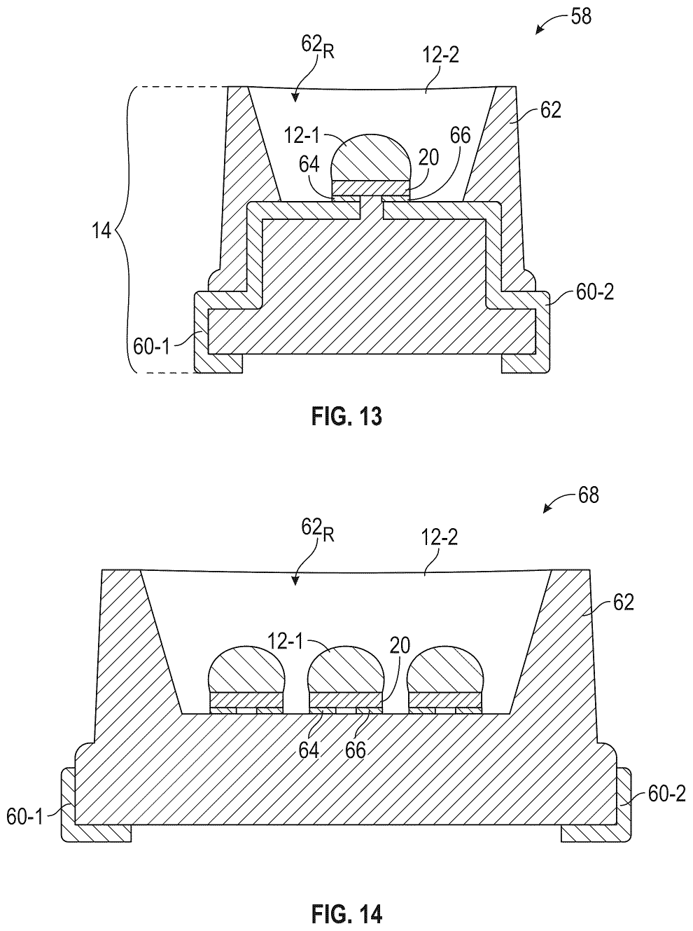

The support structure 14 in each of the previously described embodiments for FIGS. 1 to 10 may embody a submount with electrical traces or a lead frame with a corresponding housing. While FIGS. 1, 2, and 4 to 9 are specifically illustrated in the context of submounts, the principles described for the shape of the first and second lenses 12-1, 12-2 are equally applicable to lead frame structures. For specific context, FIGS. 13 to 15 are provided with specific arrangements related to embodiments where support structures embody lead frame structures.

FIG. 13 is a cross-sectional view of an LED package 58 similar to the LED package 10 of FIG. 1 for embodiments where the support structure 14 is a lead frame structure. The lead frame structure is collectively formed by a plurality of leads 60-1 to 60-2, a body or housing 62 that encases a portion of the lead frame structure, at least one LED chip 20, and the first lens 12-1 with a structure according to principles of the present disclosure. The LED chip 20 is positioned within a recess 62_{R} formed by the housing 62, and the LED chip 20 is electrically coupled to the leads 60-1 to 60-2. By way of example, the LED chip 20 is illustrated in a flip-chip configuration where anode and cathode pads 64, 66 of the LED chip 20 are mounted and electrically coupled to corresponding leads 60-1 and 60-2. In other embodiments, the LED chip 20 may be electrically coupled to at least one of the leads 60-1 and 60-2 by way of a wire bond. After the LED package 58 is fabricated, the LED package 58 may be subsequently bonded to another surface, such as within an LED display or other lighting device by way of portions of the leads 60-1 and 60-2 that extend outside a bottom of the housing 62. The first lens 12-1 may be formed on the LED chip 20 in a similar manner and with the similar widths as described with respect to FIG. 1. In various embodiments, the first lens 12-1 may have any of the self-forming shapes described above with respect to any of FIGS. 1 to 12. The second lens 12-2 may fill the recess 62_{R} to form encapsulation for LED chip 20 and the first lens 12-1. In certain embodiments, a top surface of the second lens 12-2 may form an inwardly curved surface into the recess 62_{R}. In other embodiments, the second lens 12-2 may have an outwardly curved surface relative to the recess 62_{R} for providing a different emission pattern.

FIG. 14 is a cross-sectional view of an LED package 68 similar to the LED package 58 of FIG. 13 for embodiments that include multiple LED chips 20. As illustrated, the multiple LED chips 20 may reside within the same recess 62_{R} of the housing 62. In certain aspects, each LED chip 20 may be configured to generate different peak wavelengths, such as a red-emitting LED chip, a blue-emitting LED chip, and a green-emitting LED chip. Accordingly, the LED package 68 may be well suited for placement as a pixel in an LED display. The first lens 12-1 for each LED chip 20 may have any of the self-forming shapes described above with respect to any of FIGS. 1 to 12 for color mixing and/or tailoring the overall emission profile.

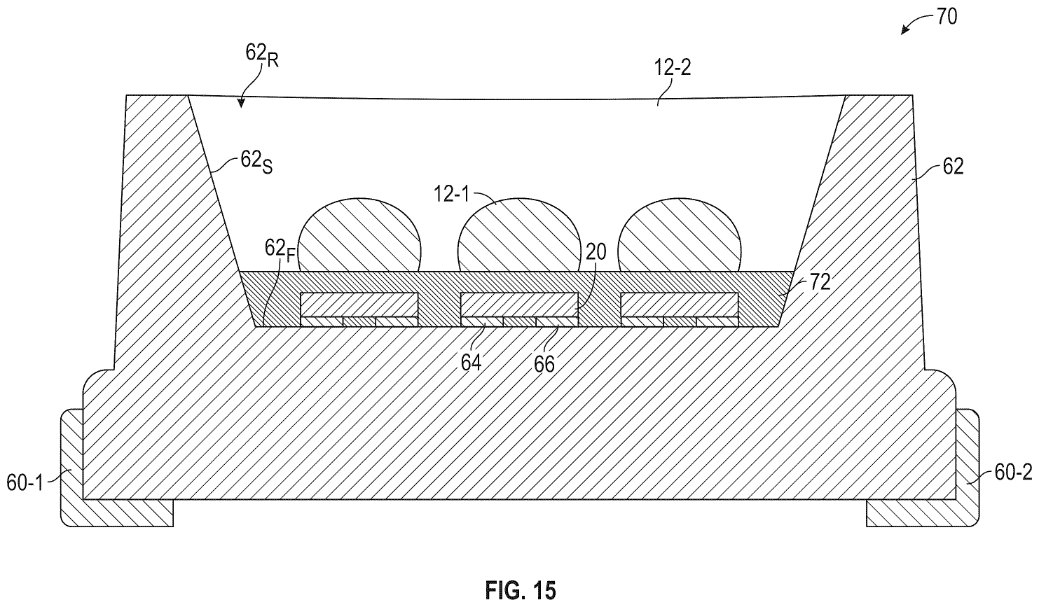

FIG. 15 is a cross-sectional view of an LED package 70 similar to the LED package 68 of FIG. 14 for embodiments for embodiments that include a lumiphoric material layer 72. As illustrated, the lumiphoric material layer 72 may be arranged on a recess floor 62_{F} of the housing 62 and covering the LED chips 20. The lumiphoric material layer 72 may further extend to contact recess sidewalls 62_{S} of the housing 62. In certain embodiments, each first lens 12-1 may be formed on a top surface of the lumiphoric material layer 72 in a position that is vertically registered with a corresponding LED chip 20 in a direction perpendicular to the recess floor 62_{F}. Each first lens 12-1 is thereby spaced from a corresponding LED chip 20 by a portion of the lumiphoric material layer 72. In this arrangement, the top surface of the lumiphoric material layer 72 may bound a bottom surface of the self-forming shape of each first lens 12-1. In operation, light from each of the LED chips 20 may be subject to wavelength conversion in the lumiphoric material layer 72 before passing through the first lens 12-1 and/or the second lens 12-2. The first lens 12-1 for each LED chip 20 may have any of the self-forming shapes described above with respect to any of FIGS. 1 to 12 for color mixing and/or tailoring the overall emission profile.

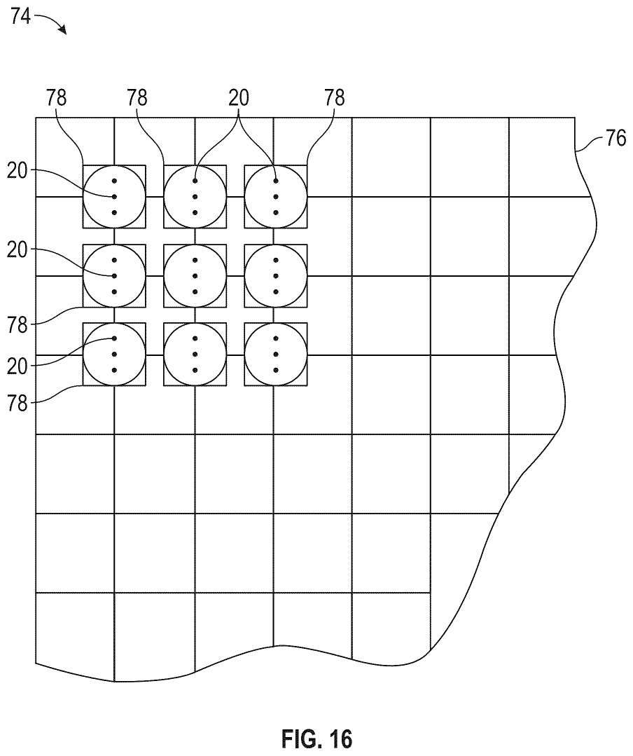

FIG. 16 is a schematic diagram of a portion of an LED device 74, such as a display screen, for example, an indoor and/or outdoor screen comprising, in general terms, a display panel including a driver printed circuit board (PCB) 76 carrying a large number of surface-mount devices (SMDs) 78 arranged in rows and columns, each SMD 78 defining a pixel. The SMDs 78 may comprise LED packages with first lenses 12-1 having any of the self-forming shapes described above with respect to any of FIGS. 1 to 12. Additionally, each SMD may represent any of the multiple chip embodiments described above with respect to FIGS. 10, 13, and 14. The SMDs 78 are electrically connected to traces or pads on the PCB 76 to respond to appropriate electrical signal processing and driver circuitry (not shown). As disclosed above, it is to be appreciated that while FIG. 16 depicts the LED chips 20 in a linear arrangement within each LED package for the SMD 78, in other embodiments, the LED chips 20 may be arranged in different configurations.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure;
an LED chip mounted on the support structure, the LED chip having a first width in a first direction parallel to the support structure;
a first lens on the LED chip, the first lens comprising:
a second width in the first direction, the second width defining a portion of the first lens that is closest to the LED chip, and the second width being less than or equal to the first width of the LED chip; and
a third width in the first direction, the third width defining a largest dimension of the first lens in the first direction, the third width being greater than the first width of the LED chip; and
a second lens on the first lens and the support structure, the second lens covering the first lens and extending on a portion of the support structure adjacent to the LED chip.

2. The LED package of claim 1, wherein the second width defines an interface between the first lens and the LED chip.

3. The LED package of claim 1, further comprising a lumiphoric material layer on the LED chip, wherein the second width defines an interface between the first lens and the lumiphoric material layer.

4. The LED package of claim 3, wherein the lumiphoric material layer laterally extends on the portion of the support structure adjacent to the LED chip.

5. The LED package of claim 1, further comprising a wire bond electrically coupled to a top surface of the LED chip, the wire bond extending through a portion of the first lens and a portion of the second lens.

6. The LED package of claim 1, wherein a surface of the first lens forms an inward depression in a direction toward the LED chip.

7. The LED package of claim 6, wherein the inward depression is centered with respect to the LED chip.

8. The LED package of claim 7, wherein the first lens forms a ring of increased thickness around a perimeter of the inward depression.

9. The LED package of claim 7, wherein a bottom of the inward depression forms a curved surface.

10. The LED package of claim 6, wherein:
the inward depression of the first lens is a first inward depression; and
a surface of the second lens forms a second inward depression in a direction toward the first inward depression.

11. The LED package of claim 10, wherein the second lens extends past perimeter edges of the support structure in the first direction.

12. The LED package of claim 10, wherein one or more side surfaces of the second lens inwardly taper toward a top surface of the support structure.

13. The LED package of claim 1, wherein the support structure comprises a submount with electrical traces.

14. The LED package of claim 1, wherein the support structure comprises a lead frame structure with a housing.

15. A light-emitting diode (LED) package comprising:
a support structure;
a plurality of LED chips mounted on the support structure, each LED chip of the plurality of LED chips having a first width in a first direction parallel to the support structure;
a separate first lens on each LED chip of the plurality of LED chips, each first lens comprising:
a second width in the first direction, the second width defining a portion of each first lens that is closest to a corresponding LED chip of the plurality of LED chips, and the second width being less than or equal to the first width; and
a third width in the first direction, the third width defining a largest dimension of each first lens in the first direction, the third width being greater than the first width; and
a second lens on the plurality of LED chips and the support structure, the second lens covering each first lens and extending on a portion of the support structure adjacent to the plurality of LED chips.

16. The LED package of claim 15, wherein the second lens is positioned between neighboring LED chips of the plurality of LED chips.

17. The LED package of claim 15, wherein the support structure comprises a lead frame structure with a housing, and the plurality of LED chips are positioned within a same recess of the housing.

18. The LED package of claim 17, further comprising a lumiphoric material layer positioned in the recess and covering the plurality of LED chips, wherein each first lens is spaced from the plurality of LED chips by a portion of the lumiphoric material layer.

19. A light-emitting diode (LED) package comprising:
a support structure;
an LED chip mounted on the support structure;
a first lens on the LED chip and on a portion of the support structure adjacent to the LED chip, the first lens comprising one or more side surfaces that inwardly taper in a direction toward the support structure; and
a second lens on the first lens and the support structure, the second lens covering the first lens and extending on a portion of the support structure adjacent to the first lens.

20. The LED package of claim 19, wherein a surface of the first lens forms an inward depression in a direction toward the LED chip.

21. The LED package of claim 20, wherein the inward depression is centered with respect to the LED chip.

22. The LED package of claim 20, wherein:
the inward depression of the first lens is a first inward depression; and
a surface of the second lens forms a second inward depression in a direction toward the first inward depression.

23. The LED package of claim 19, further comprising a light-altering material having a white color and positioned between the second lens and the support structure.

24. The LED package of claim 23, wherein a portion of the light-altering material is positioned between the first lens and the support structure in a direction perpendicular to the support structure.
